(19) United States
(12) Patent Application Publication
(10) Pub. No.: US 2007/0195850 A1
(43) Pub. Date: Aug. 23, 2007

(54) Diode laser array stack

(75) Inventors: Holger Schluter, Princeton, NJ (US); Claus Schnitzler, Kreuzau (DE)

Correspondence Address: FISH & RICHARDSON PC, P.O. BOX 1022, MINNEAPOLIS, MN, 55440-1022, US

(73) Assignee: TRUMPF PHOTONICS INC., Cranbury, NJ (US)

(21) Appl. No.: 11/569,894

(22) PCT Filed: Oct. 8, 2004
(86) PCT No.: PCT/US04/33330

§ 371 Date: Mar. 29, 2007

Related U.S. Application Data
(60) Provisional application No. 60/575,390, filed on Jun. 1, 2004.

(51) Int. Cl. H01S 5/00; G02B 6/32

(52) U.S. Cl. 372/50.124; 385/33; 372/50.12

(57) ABSTRACT

A light generating apparatus is operably coupled to an optical fiber (10) with a cladding (5) and a core (4) defining a core diameter. The optical fiber (10) has a numerical aperture, and the product of the numerical aperture of the fiber and one-half the diameter of the core (4) is less than or substantially equal to 400 millimeter-milliradians. The apparatus includes a plurality (7) of laser diode arrays (6, 23, 55), each array comprising at least one light emitting region (1, 24) adapted for emitting light in a individual beam (21, 11). The plurality of laser diode arrays (6, 23, 55) are arranged such that light from the individual beams (21, 11) is combined in a combined beam, and the combined beam has a first far-field, half-angle divergence in a first direction and a first waist dimension in the first direction, and a second far-field, half-angle divergence in a second direction, substantially perpendicular to the first direction, and a second waist dimension in the second direction. The laser diode arrays (6, 23, 55) are arranged relative to the optical fiber (10) to couple light output from the laser diode arrays (6, 23, 55) into the core of the fiber at an end of the fiber. The product of the first far-field, half-angle divergence and the first waist dimension is equal to or smaller than one-half of the product of the core diameter and a numerical aperture of the fiber (10), and the product of the second far-field, half-angle divergence and the second waist dimension is equal to or smaller than one-half of the product of the core diameter and the numerical aperture.

### TECHNICAL FIELD

This disclosure relates to diode lasers, and more particularly to diode laser array stacks.

### BACKGROUND

High-power diode lasers are used in many different applications. The usefulness of a laser for a specific application can be characterized by the laser's output power, the spectral line width of the output light, and the spatial beam quality of the output light.

The spatial beam quality can be characterized in several ways. For example, a wavelength independent characterization of the spatial beam quality is provided by the beam parameter product (“BPP”), which is defined as the product of the beam waist (i.e., the half diameter of the beam at the so-called “waist” position), w₀, and the far-field, half-angle divergence of the beam, Θ₀:
BPP=w₀Θ₀ (1)

As another example, a nondimensional characterization of the spatial beam quality is provided by the beam quality factor, M² or Q, where the beam quality factor is given by
M²=1/Q=πw₀θ₀/λ (2)
with λ being the wavelength of the output laser light.

A laser operating in the TEM₀₀ mode and emitting a Gaussian beam has the lowest possible BPP (M²=1). Ridge waveguide and gain-guided laser diodes operating in this mode are called single mode emitters and typically consist of a 3 μm wide stripe (along the lateral axis of the laser). The output power of these emitters is limited to about 1 W due to catastrophic optical damage (“COD”) of the laser facet. To increase the facet area, so called tapered emitters can be used.

To achieve higher power output from a semiconductor laser diode, a relatively wide effective lateral width of the active material in the laser can be used. Such devices are known as “wide stripe emitters,” broad stripe emitters,” or “multimode devices.” However, when the effective lateral width of the active material is greater than several times the laser output wavelength, gain can occur in higher order spatial modes of the resonant cavity, which can reduce the spatial beam quality of the output laser light.

Multiple wide stripe emitters and/or single mode emitters can be fabricated side-by-side on a single chip to make an array of single emitters. The output light of multiple individual laser diode emitters in an array can be combined incoherently to increase the overall output power from the chip. However, the quality of the combined output beam generally decreases with the number of individual emitters in an array.

The total output beam of these laser diode arrays is generally strongly asymmetric. For example, a typical beam parameter product (“BPP”) of a 10 mm wide array along the slow axis (i.e., the lateral axis of the laser diode) can be BPP_{slow}=500 mm*mrad, while a typical BPP of an array along the fast axis (i.e., the vertical axis of the laser diode), where the device is typically operating in the TEM₀₀ mode, can be BPP_{Fast}=0.3 mm*mrad.

Many laser applications require a symmetric beam that is typically delivered from an optical fiber, and, therefore, power must be coupled from a laser diode array into a fiber. However, it is difficult to couple the strongly asymmetric beam of the array into a fiber. The output beam of from an array can be cut into parts and rearranged (e.g., by step mirrors, tilted plates, or tilted prisms), so that the BPP of the rearranged beam is equal in both axes, but complicated optical systems are necessary to achieve a symmetric beam in such a manner. Therefore, it is desirable to have a light source that produces a high power output beam that can be coupled into an optical fiber.

### SUMMARY OF THE INVENTION

The invention is based, in part, on the recognition that coupling light from a plurality of laser diodes into an optical fiber can be enhanced by matching the optical properties of an output beam from a stack of laser diode arrays with the optical properties of the optical fiber.

According to one aspect of the invention, a light generating apparatus is operably coupled to an optical fiber with a cladding and a core defining a core diameter. The optical fiber has a numerical aperture and the product of the numerical aperture of the fiber and one-half the diameter of core is less than or substantially equal to 400 millimeter-milliradians. The apparatus includes a plurality of laser diode arrays, each array having at least one light emitting region adapted for emitting light in a individual beam. The plurality of laser diode arrays are arranged such that light from the individual beams is combined in a combined beam, and the combined beam having a first far-field, half-angle divergence in a first direction and a first waist dimension in the first direction, and a second far-field, half-angle divergence in a second direction, substantially perpendicular to the first direction, and a second waist dimension in the second direction. The laser diode arrays are arranged relative to the optical fiber to couple light output from the laser diode arrays into the core of the fiber at an end of the fiber. The product of the first far-field, half-angle divergence and the first waist dimension is equal to or smaller than one-half of the product of the core diameter and a numerical aperture of the fiber, and the product of the second far-field, half-angle divergence and the second waist dimension is equal to or smaller than one-half of the product of the core diameter and the numerical aperture.

Embodiments can include one or more of the following features. For example, the product of the numerical aperture of the fiber and one-half the diameter of core can be less than or substantially equal to 110 millimeter-milliradians, particularly less than or substantially equal to 6 millimeter-milliradians. The at least one light emitting region can be a multi-mode light emitting region. Each array can include a plurality of M light emitting regions, where M is an integer. Each light emitting region of each array can include a stripe width (wₛ), and the light emitting regions of an array can be arranged adjacent to each other and can be separated from adjacent regions by a center-to-center distance (pₛ) particularly where the first waist dimension is substantially equal to 0.5·[(M−1)·pₛ+wₛ].

The arrays can define both a fast axis and a slow axis, and the apparatus can further include a lens for collimating light emitted in an individual beam from each array along a direction of the slow axis. Each array can include a plurality of M light emitting regions arranged adjacent to each other and separated from adjacent regions by a center-to-center distance (pₛ), where M is an integer, and the individual beam can have a waist dimension (w_{beam}) after collimation by the lens in a direction substantially parallel to the slow axis, where the first waist dimension is substantially equal to 0.5·[(M−1)·pₛ+2·w_{beam}].

The plurality of laser diode arrays can be arranged such that light output from individual arrays is coupled into the fiber core in substantially parallel stripes of light. The plurality of N laser diode arrays are arranged in a stack, where N is an integer. Each light emitting region can have a height (t), and the arrays can be stacked to have a center-to-center distance (qₐ) between adjacent arrays in the stack, such that the second waist dimension is substantially equal to 0.5·[(N−1)·qₐ+t]. The arrays can define a fast axis and a slow axis, and the apparatus can further include a microlens corresponding to each array for collimating light emitted in an individual beams from each array along the direction of the fast axis.

The apparatus can include a plurality of N arrays, where N is an integer, and where individual beams have a waist dimension (h) after collimation by the microlenses in a direction substantially parallel to the fast axis, where the individual beams are combined in a stack, such that adjacent beams in the stack have a center-to-center distance, qₛ, and where the second waist dimension is substantially equal to 0.5·[(N−1)·qₛ+h].

The light emitting regions can include multimode emitting regions, particularly multimode emitting regions that are at least 10 μm wide.

The product of the first far-field, half-angle divergence and the first waist dimension can be equal to or smaller than 1/2\sqrt{2} times the product of one-half the core diameter and the numerical aperture, and the product of the second far-field, half-angle divergence and the second waist dimension can be equal to or smaller than 1/2\sqrt{2} times the product of one-half the core diameter and the numerical aperture.

The plurality of laser diode arrays can include N laser diode arrays, where N is an integer, where the beams of the N arrays can be combined in a combined beam composed of a stack of substantially parallel light stripes of individual beams from the individual arrays, and where an individual beams emitted from an individual array can have a first far-field, half-angle divergence (Θ₁ⁱ) and a first waist dimension (w₁ⁱ) in a direction substantially parallel to a the first direction, and a second far-field, half-angle divergence (Θ₂), and a second waist dimension (w₂ ) in a direction substantially parallel to the second direction, where the product of Θ₁ⁱ and w₁ⁱ, for an i^{th} parallel light stripe in the combined beam is equal to or smaller than the product of one-half the core diameter (d), the numerical aperture (NA), and the factor

$$\sqrt{1 - {( \frac{- NA \cdot \frac{d}{2} + 2 \cdot ( i - \frac{1}{2} ) \cdot {Θ}_{2} \cdot {w}_{2}}{NA \cdot d / 2} )}^{2}} ,$$

where i is an integer index that takes the value i=1 . . . N, representing sequentially the i^{th} parallel light stripe in the combined beam, where the first light stripe is at the bottom of the stack and the N^{th} light stripe is at the top of the stack, and where the product of Θ₂ and w₂ is equal to or smaller than product of one-half the core diameter and the numerical aperture.

The at least one light emitting region can be a multi-mode light emitting region. Each array can include a plurality of M light emitting regions, where M is an integer. Each light emitting region can include a stripe width (wₛ), and the light emitting regions of an array can be arranged adjacent to each other and can be separated from adjacent regions by a center-to-center distance (pₛ).

The arrays include a fast axis and a slow axis, and the apparatus can further include a lens for collimating light emitted in an individual beam from an each array along the direction of the slow axis. The plurality of N laser diode arrays can arranged in a stack, where each light emitting region has a height (t), where the arrays are stacked such that adjacent arrays in the stack have a center-to-center distance (qₛ), and where the second waist dimension is substantially equal to 0.5·[(N−1)·qₛ+t].

The arrays can define a fast axis and a slow axis, and the apparatus can further include a microlens corresponding to each array for collimating light emitted in an individual beams from each array along a direction of the fast axis. Individual beams can have a waist dimension (h) after collimation by the microlenses in a direction substantially parallel to the fast axis, where the individual beams are combined in a stack, such that adjacent arrays in the stack have a center-to-center distance (qₛ), and wherein the second waist dimension is substantially equal to 0.5·[(N−1)·qₛ+h].

### DESCRIPTION OF DRAWINGS

FIG. 1 is a schematic top view of a laser diode array, an optical fiber, and a lens for coupling light from the array into the fiber.

FIG. 2 is a top view of an array of four single emitters and an attached slow-axis collimation array

FIG. 3 is a schematic side view of a stack of diode laser array having microlenses at the output facet of the arrays.

FIG. 4 is a graph of the overlap of the beam parameter product of laser beam outputs from different laser diode stacks with one quarter of the cross section of an optical fiber.

FIGS. 5a, 5b, and 5c are schematic side top, and perspective views of a system for coupling light from a laser diode array stack into an optical fiber.

FIG. 6a is a plot of a spatial intensity distribution of light emitted from a diode laser array stack at a focal plane of an optical system.

FIG. 6b is a plot of an angular intensity distribution of light emitted from a diode laser array stack at a the focal plane in the optical system.

FIG. 7a is a plot of a spatial intensity distribution of light emitted from a diode laser array stack at an entrance pupil of a fiber.

FIG. 7b is a plot of an angular intensity distribution of light emitted from a diode laser array stack at the entrance pupil of the fiber.

FIG. 8a is a plot of a spatial intensity distribution of light emitted from a diode laser array stack at the entrance pupil of the fiber.

FIG. 8b is a plot of an angular intensity distribution of light emitted from a diode laser array stack at the entrance pupil of a fiber.

FIG. 9a is a schematic view of seven elements of a 14-element laser diode array stack.

FIG. 9b is a plot of a spatial intensity distribution of light emitted from a diode laser array stack at the entrance pupil of a fiber.

FIG. 9c is a plot of an angular intensity distribution of light emitted from a diode laser array stack at the entrance pupil of a fiber.

FIG. 10a is a schematic side view of a diode laser array stack.

FIGS. 10b and 10c are schematic top and side views of a configuration of a stack of diode laser arrays.

FIG. 10d is a graph of the light output from the diode laser array stack of FIGS. 10a, 10b, and 10c.

FIG. 11 is a schematic view of a wavelength multiplexing scheme.

FIG. 12 is a schematic view of a polarization multiplexing scheme.

### DESCRIPTION

An arrangement of laser diodes having a specific geometry and an optical system for coupling light from the laser diodes into an optical fiber is disclosed.

The arrangement can be used to optimize coupling of the radiation output from the laser diodes into the fiber and to increase the amount of laser power that can be coupled into one end of an optical fiber and transported to the other end of the fiber.

A step-index optical fiber has a core and a cladding with different indices of refraction and diameters, which determine the spatial size and angular divergence of a light beam that can be coupled successfully into an end of the fiber. As explained in further detail below, N laser diode arrays of M laser diodes (where M and N are integers) can be arranged, based on the characteristic parameters of an optical fiber, in such a way that light from the arrays is coupled optimally into the fiber.

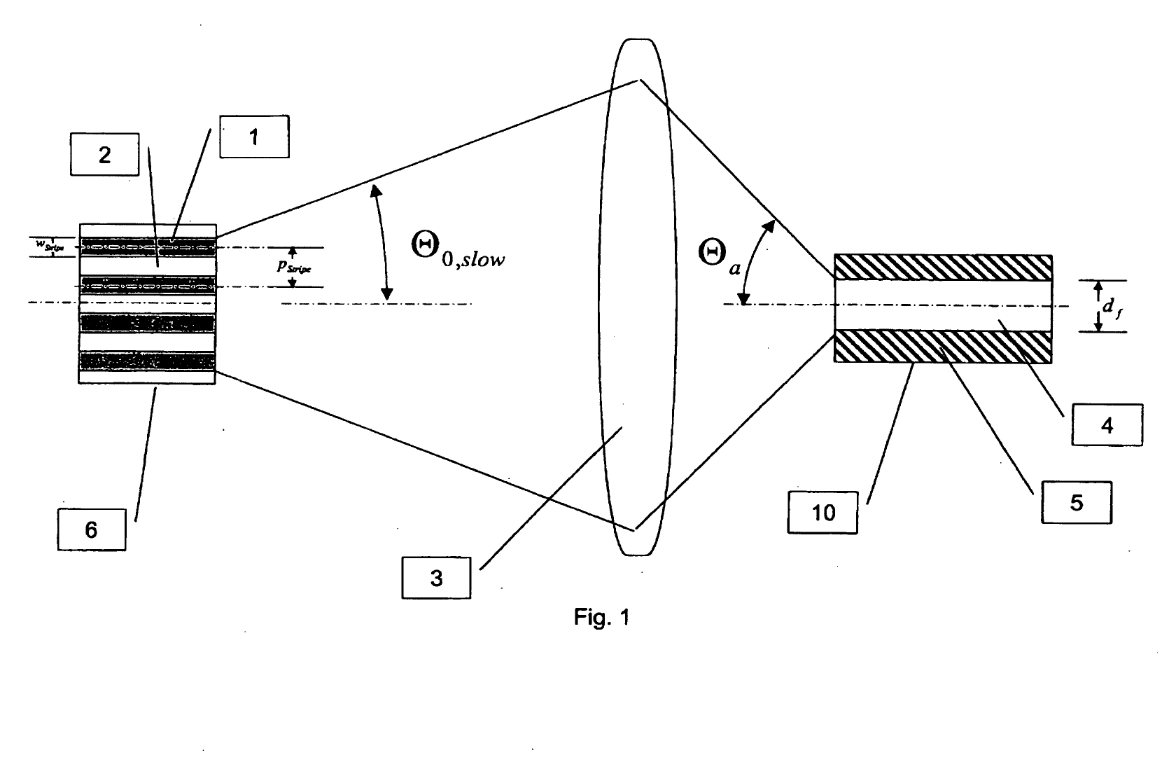

As shown in FIG. 1, a light emitting device (e.g., a semiconductor diode laser) 6 can include one or more light emitting regions 1. The light emitting region(s) 1 can be part of a single chip light emitting device, and, when the chip includes more than one emitting region 1 the chip may be known as a light emitting array (e.g., a diode laser array). The light emitting regions I can be formed in a semiconductor chip by patterning multiple contact strips 1 on the device 6 for injecting electrical energy into a light generating layer within the device. Thus, multiple emitting regions (“emitters”) 1 of the device 6 under the contact stripes emit light and are separated by non-emitting areas 2 between the adjacent emitters 1. The width of the emitters, w_{Stripe}, which can be about several μm to about several hundred μm, and the center-to-center distance between adjacent emitters, p_{Stripe}, can be chosen to optimize different characteristic parameters of the diode laser array 6 (e.g., the fill factor of the array, the beam quality per emitter, and/or the thermal behavior of the array).

Each emitting region 1 can emit light (e.g., laser light) in an output beam. The output beam from an emitting region typically diverges after leaving the semiconductor device 6, and, because the width of the emitting regions 1 is typically much greater than the thickness of the emitting regions (i.e., in a direction perpendicular to the page shown in FIG. 1), the divergence angle of the output beams, Θ_{0,slow}, in the direction parallel to the width of the emitters 1 is typically lower than the divergence angle, Θ_{0,fast}, of the output beam in the direction parallel to the thickness (i.e. in a direction perpendicular to the page shown in FIG. 1). For example, Θ_{0,slow}, can be about one order of magnitude smaller than Θ_{0,fast}, for an emitter 1 having a width of about 100 μm and a thickness of about 1 μm. The direction of low beam divergence (i.e., parallel to the width of an emitter 1) can be known as the “slow axis” of the emitter 1, and the direction of high beam divergence (i.e., perpendicular to the width and length of the emitter 1) can be known as the “fast axis” of the emitter 1.

Typically, a light emitting device 6 having multiple emitting regions 1 does not emit light from across the entire width of the device. Rather, light output from multiple laser diode emitters 1 arranged in an array 6 has a “fill factor” along the slow axis of the array 6 (“FF_{Slow}”), where FF_{Slow} is defined as the total width of the portions of the laser diode emitters 1 that emit light divided by the total width of the array 6 and is less than 1. For an array 6 of wide-stripe, gain-guided laser diodes 1, the portion of the laser diodes 1 that emit light is approximated by the width of the contact stripe, w_{Stripe}, of the laser diodes 1. When M wide-stripe diode lasers having contact stripe widths, w_{Stripe}, are arranged in a linear array 6, with a center-to-center distance (“p_{Stripe}”) between two neighboring array elements 1, FF_{Slow} for the array 6 is given by:

$${FF}_{slow} = \frac{M \cdot {w}_{stripe}}{{w}_{stripe} + ( M - 1 ) {p}_{stripe}} , \qquad ( 3 )$$

where M is an integer. When multiple identical arrays 6 are stacked vertically, as described in more detail below, the FF_{Slow} for the stack of arrays 6 is equal to the FF_{Slow} of an individual array 6 in the stack. For other types of semiconductor lasers (e.g., tapered waveguide, heterostructure lasers) the lateral width of the chip that emits light need is not necessarily equal to the width of a contact stripe, and the width of the beam emitted from the chip is defined by the waist, w_{waist}, of the cavity mode at the emission facet of the laser. In such a case 2*w_{waist}, must be substituted for wₛₜᵣᵢₚₑ, and the center-to-center spacing of adjacent emission beams must be substituted for pₛₜᵣᵢₚₑ, in equation (3).

The total radiation beam output from an array 6 of M emitters 1 can be characterized by the product of the divergence angle of the beam and the width of the beam. Thus, a beam parameter product along the slow axis of an array of M single emitters (“BPP_{Slow,Array}”) can be related to the width of the individual emitting stripes, w_{Stripe}, (where the width, w_{Stripe}, is typically twice the waist radius w₀ of a single emitter) according to the equation:

$${BPP}_{Slow , Array} = \frac{0.5 \cdot {w}_{stripe} \cdot M}{{FF}_{Slow}} \cdot {θ}_{0 , Slow} \qquad ( 4 )$$

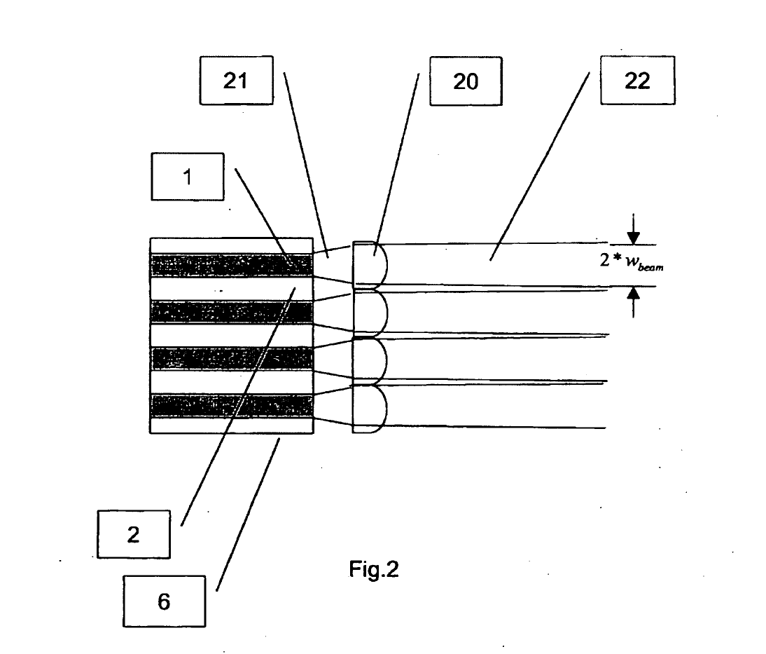

FIG. 2 shows a top view of a laser diode array 6 and output beams emitted from the individual laser diodes in the slow axis of beams. The array 6 includes non-emitting zones 2 and emitting zones 1 that emit output beams of light 21 into an array of cylindrical lenses 20. The lenses 20 collimate the output beams 21 to form an array of collimated beams 22 after the collimating lenses 20. The collimated beams 22 can then be guided into an optical fiber, as explained in more detail below. Typically, the individual collimated beams 22 have greater waist dimensions, w_{beam}, and lower angular divergences than the beams 21 emitted directly from the individual laser diodes. Although the BPP_{Slow} of an individual collimated beam 22 is substantially equal to the BPP_{Slow} of an original output beam 21, the cylindrical collimating lenses 20 can reduce the BPP of the combined beam due to the combination of all of the collimated output beams 22 by increasing the fill factor of the combined beam after the collimating lenses 20. Therefore, a beam parameter product in the slow axis direction can be defined for the beam emitted by the array in combination with collimating optics, such as collimating lenses 20. The BPP_{Slow,Array} of this combined output beam is defined as in equation (4), except that 2*w_{beam} is substituted for wₛₜᵣᵢₚₑ and the angular divergence of the combined beam in the slow axis is used in equations (3) and (4).

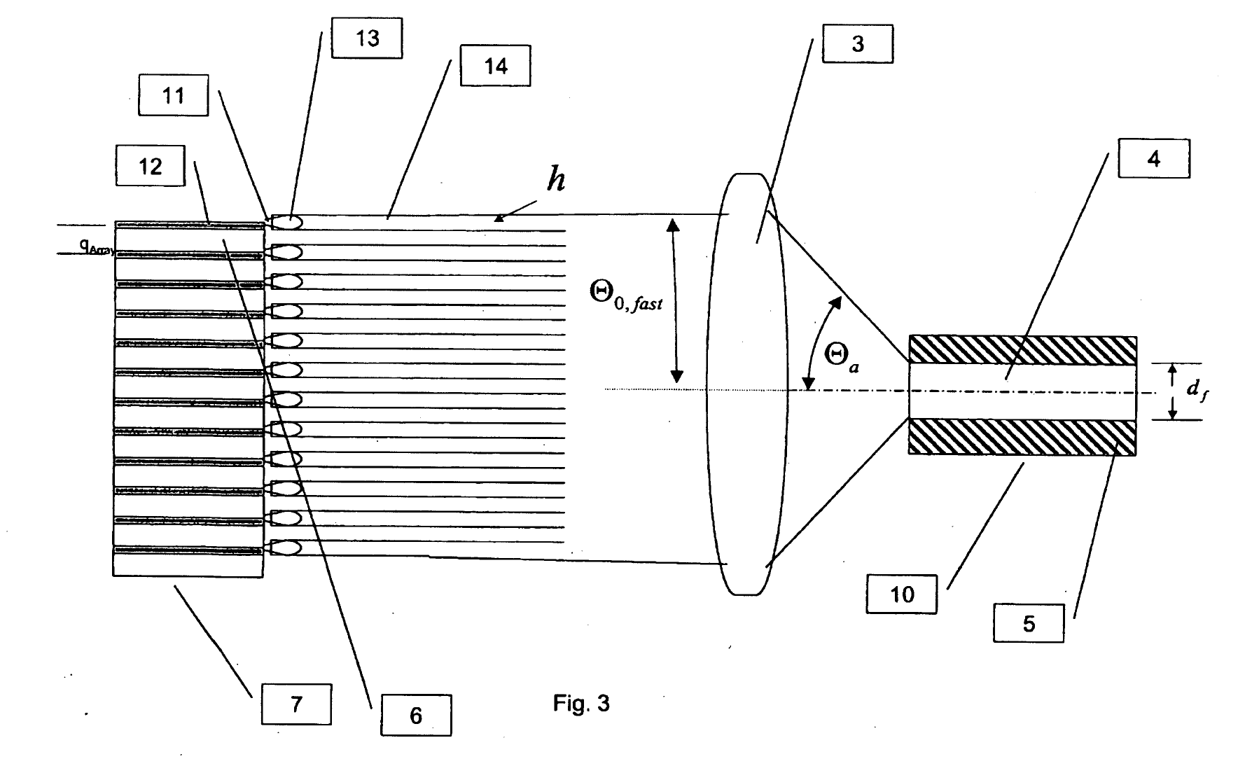

As shown in FIG. 3, multiple diode laser arrays 6 can be stacked in the fast axis direction, perpendicular to the slow axis direction. A stack 7 of the light output from multiple arrays 6 can be achieved either by mechanically mounting multiple arrays 6 top of each other in a stack 7 or by optically arranging the output beams of different arrays 6 on vertically top of each other. Radiation beams 11 emitted from the active and waveguide regions 12 of the arrays 6 within a stack 7 have a high angular divergence in the fast axis direction. However cylindrical microlenses 13 can be used to collimate the beams 11, such that the collimated beams 14 that emerge from the microlenses 13 have a height, h, at a position just past the mircolenses 13, and a divergence angle in the fast axis direction after collimation, Θ_{0,fast}, that is typically on the order of about 1 mrad. Thus, the microlenses 13 can increase the fill factor along the fast axis direction, FF_{Fast}, of the beam emitted from the diode laser stack 7, while increasing the height of individual beams.

For a stack 7 of N laser diode arrays 6 that each emit beams with a height, h_{Array}, and that have a center-to-center vertical distance to beams from adjacent stacked arrays, q_{Array}, the FF_{Fast} of the total combined beam emitted from the stack of arrays can be defined as:

$${FF}_{Fast} = \frac{N \cdot {h}_{Array}}{{h}_{Array} + ( N - 1 ) \cdot {q}_{Array}} . \qquad ( 5 )$$

Thus, the fast axis beam parameter product of a stack 7 of multiple arrays 6 (“BPP_{Fast,Stack}”) is correlated with the height of the beams emitted from individual arrays, h, according to the relation:

$${BPP}_{Fast , Stack} = \frac{0.5 \cdot h \cdot N}{{FF}_{Fast}} \cdot {θ}_{0 , Fast} \qquad ( 6 )$$

Equations (3)-(6) are also valid for single emitter arrays (i.e., M=1) and/or single array stacks (i.e., N=1). Because BPP_{Slow,Array} does not change when multiple identical arrays are stacked on top of each other, we can write:

$$\text{?} \text{?} \text{indicates text missing or illegible when filed} \qquad ( 8 )$$

Referring to FIGS. 1 and 3, subsequent to collimation by the fast axis microlenses 13 and/or slow axis collimation lenses 20, the radiation in the beams can be focused with one or more optical elements 3 onto the fiber 10 having a core 4 with a diameter, d_{f}, and a cladding 5 surrounding the core.

The light emitted from one or more emitting regions 1 can be imaged or focused by one or more optical elements 3 (e.g. a lens), onto a step index optical fiber that includes a core 4 having a diameter, d_{f}, and a cladding 5 and coupled into the fiber 10. For example, the fiber can have a core diameter of about 10 μm—to about 1 mm, although larger diameters are also possible, in which case the fiber may be known as a rod. Light can propagate within the fiber 10 due to total internal reflection at the interface between the core 4 and the cladding 5, which have different indices of refraction, n₁ and n₂, respectively. The maximum angle of a light ray with respect to the axis of the fiber 10 under which total internal reflection within the fiber can occur can be known as the acceptance angle of the fiber, Θₛ, and depends on the indices of refraction of the fiber's core 4 and cladding 5 according to the relation Θ=sin⁻¹(\sqrt{n₁²−n₂²}). A numerical aperture of the fiber 10, NA, can be defined as being equal to the sine of the fiber's acceptance angle, Θₛ, i.e., NA=\sqrt{n₁²−n₂²}. Typical optical fibers have a NA of about 0.1 to about 0.5. Thus, a beam parameter product of a laser beam that the fiber can accept without appreciable insertion power loss, BPP_{Fiber}, can be defined in terms of these parameters as:
BPP_{Fiber}=0.5·d_{f}·sin Θₛ=0.5·d_{f}·NA (9)
For a typical optical fiber 10 having a core diameter of 100 μm and a NA of 0.22, equation (3) gives BPP_{Fiber}=11 mm*mrad. Particular fibers can have a NA of 0.22 and core diameters of 3.64 mm, 1 mm, and 50 μm, giving BPP_{Fiber} values of 400 mm*mrad, 110 mm*mrad, and 6 mm*mrad, respectively.

A tack 7s of laser diode arrays 6 can be tailored to produce an output beam having characteristics that are well matched to the characteristics of an optical fiber 10 into which the beam is to be coupled. For example, a stack 7 can produce a beam having characteristics to, such that power coupled from the stack 7 into the fiber 10 is maximized, and/or such that the power is coupled into the fiber 10 in a low-loss fiber mode. Matching of the BPP of the beam output from the stack 7 with the BPP of the fiber 10 can be used to determine optimal designs of such stacks.

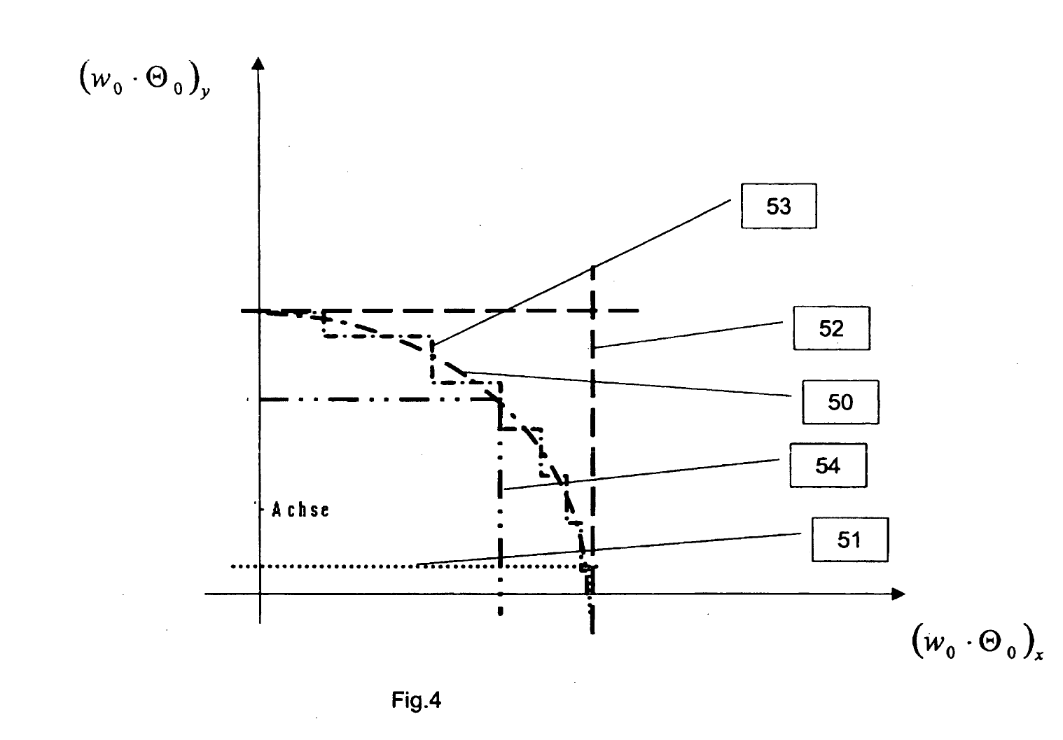

For example, FIG. 4 shows a two-dimensional graph representing the overlap of the parameter product, w₀θ₀, of light emitted from three different laser diode stacks 7 with the beam parameter-product of an optical fiber 10. Three cases, corresponding to over-, under-, and optimum-filling of the fiber are shown in the graph of FIG. 4. Different light emitting elements (e.g., a laser diode, an array of laser diodes, or a stack of laser diode arrays) characterized by their BPPs along the fast axis and slow axis occupy different areas in this diagram, as indicated by the different lines in the graph. A quarter circle 50 represents the acceptance angle, Θₛ, multiplied by half the core diameter, d_{f}, of a symmetric optical fiber. The light output from a single rectangular shaped array is represented by a rectangle 51, where the BPP_{Slow} of the array in the slow axis (i.e., the x-axis in the graph) coincides with the BPP_{Fiber} of the fiber.

By stacking the light output from several arrays 6 on top of each other, the area delimited by line 52, the x-axis, and the y-axis can be occupied, and the overlap of this area with the area delimited by the line 50 and the x- and y-axes defines the coupling efficiency that can be achieved for the stack. The area enclosed by line 52 and the axes shows a case in BPP_{Slow,Array}=BPP_{Fast,Stack}=BPP_{Fiber}, and which can be known as a case of overfilling the fiber. The BPP of the light output from the stack 7 can fulfill this condition by selecting the values M*w_{Stripe}/FF_{Slow} and N*h_{array}/FF_{Fast} of the laser diode array stack 7 to ensure that BPP_{Slow,Array}=BPP_{Fast,Stack}=BPP_{Fiber}. The case of overfilling the fiber ensures that the portion of light emitted from the stack 7 that has a BPP within the line 50 is coupled into one end of the fiber 10 without insertion loss and coupled to the other end of the fiber 10, but also that the portion of the output beam that lies between lines 50 and 52 is not coupled from one end of the fiber to the other. However, in many applications for a beam launched into a fiber with BPP_{Slow,Array}=BPP_{Fast,Stack}=FPP_{Fiber}, light may escape the fiber as it propagates along the axis of the fiber when the light encounters bends and imperfections in the fiber and laser power will be lost between the ends of the fiber. Moreover, an optical system (e.g., a system used for laser cutting) coupled to the output end of the fiber may demand a higher beam quality (i.e., a lower BPP) than the minimum beam quality that can be transported in the fiber from end to end (i.e., BPP_{Fiber}) Thus, BPP_{Slow,Array} and BPP_{Fast,Stack} can be selected to be substantially equal to each other but to be less than BPP_{Fiber} to ensure a safety margin in case the fiber is bent, stressed, or has other imperfections. For example, when coupling light from a stack 7 into a fiber having a numerical aperture of 0.22 and a core diameter of 100 μm, the BPP in the fast- and slow-axes of the beam that is launched into the fiber can be selected to be about one-half of the BPP of the fiber (i.e., BPP_{Launch}=0.5*100 μm*0.1=5 mm*mrad).

The area delimited by line 54 and the axes shows a case in which

$${BPP}_{Slow , Array} = {BPP}_{Fast , Stack} = \frac{1}{\sqrt{2}} {BPP}_{Fiber} ,$$

and which can be known as a case of underfilling the fiber. The BPP of the light output from the stack 7 can fulfill this condition by selecting the values M*w_{Stripe}/FF_{Slow} and N*h/FF_{Fast} of the laser diode array stack 7 to ensure that

$${BPP}_{Slow , Array} = {BPP}_{Fast , Stack} = \frac{1}{\sqrt{2}} {BPP}_{Fiber} .$$

The case of underfilling the fiber ensures that power is not lost when coupling into the fiber. However, light having a BPP near the corner of the square defined by line 54 and being close to the line 50 is scattered off the core/cladding interface as it propagates through the fiber such that the maximum BPP of the beam exiting the fiber is greater than the BPP_{Slow,Array} and BPP_{Fast,Stack} of the beam launched into the fiber. Again, to ensure a safety margin, the BPP_{Slow,Array} and BPP_{Fast,Stack} can be selected to be substantially equal to each other but less than

$$\frac{1}{\sqrt{2}} {BPP}_{Fiber}$$

to ensure a safety margin in case the fiber is bent, stressed, has other imperfections, or if an application demands such a higher beam quality.

An optimum overlap between the total beam parameter product of light emitted from a laser diode stack 7 with the radius of the core of an optical fiber multiplied by the acceptance angle of the fiber can be achieved by stacking arrays having different BPP_{Slow}, such that the total BPP of light emitted from the stack overlaps nearly identically with the quarter circle representing the BPP_{Fiber} of the optical fiber. A laser diode array stack 7 exhibiting a light output having a BPP_{Fast} in the fast axis and varying BPP_{slow} in the slow axis, as shown in trace 53, leads to a high overlap with the BPP_{Fiber} of the optical fiber and therefore to a high coupling efficiency and maximum power in the fiber. For example, for a stack 7 of N arrays 6, the BPP_{Fast,Stack} can be selected to be equal to BPP_{Fiber} and BPP_{Slow,Array} individual arrays 6 of the stack 7 can be selected to vary for the N arrays approximately according to the equation,

$${BPP}_{Slow , Array , i} \cdot \sqrt{1 - {( \frac{- {BPP}_{Fiber} + 2 \cdot ( i - \frac{1}{2} ) \cdot {BPP}_{Fast}}{{BPP}_{Fiber}} )}^{2}}$$

where i=1−N, i=1 is the bottom-most array of the stack, and i=N is the top-most array of the stack, which we call “optimum fiber filling,” and which ensures maximum power efficiency and beam quality of the beam transmitted by the fiber for a given BPP of a single array in the fast-axis. Again, to ensure a safety factor, the BPP of the beam in the fast and slow axis directions can be smaller than given by the equations above, for example by a constant factor, c, that is less than 1.

In addition, the fill factor in the fast axis and/or in the slow axis can be optimized by using fast axis collimation lenses and/or slow axis collimation lenses or by optically stacking different output beams while retaining the above conditions for the BPP in the slow axis and in the fast axis. This ensures that maximum power of the beam is transmitted through the fiber of given beam quality.

The optical system can include separate beam shaping optics for the slow and the fast axis, which ensure that not only the BPP's fulfill the above-mentioned requirements, but also, that the individual beam sizes at the fiber and the far field angles match the numerical aperture NA of the fiber and the fiber core's diameter. Up to this point, the overall BPP of a light source has been considered as a characteristic parameter of the light source. However, the beam parameter product is the product of the width of a beam or combinations of beams in real space and angular space, and the shape and divergence of the beam along the slow- and fast axes can be different. Typically, the intensity distribution in the slow axis direction for light emitted from a multimode laser diode is relatively constant in the central portion of the intensity distribution and falls of sharply at the edges of the distribution (i.e., the distribution has a top hat like shape) in real and angular space. In the fast axis direction, the intensity distribution is more like a Gaussian in real and angular space. In general, the transfer efficiency of a real beam emitted from a laser diode into an optical fiber can be characterized by the product of overlap of the fiber core's cross section in real space (e.g., defined by the fiber core's diameter, d_{f}) with the spatial intensity distribution of light from the light source (e.g., the laser diode, array, or stack) and the overlap of the fiber's angular acceptance (e.g., the NA of the fiber) with the angular distribution of light emitted from the light source.

For example, in a application that uses an optical fiber having a core diameter of 100 μm and demanding a numerical aperture of 0.1 for the beam that exits the fiber, the BPP of the beam to be launched into the fiber must be less than about 5 mm*mrad. This is approximately equal to the BPP_{Slow} of a single emitter having a 100 μm stripe width and a slow axis divergence angle of 6 degrees. Assuming that the single emitter has a BPP_{Fast} of 0.36 mm*mrad in the fast axis, a stack of 14 emitters can be stacked on top of each other such that BPP_{Fast,Stack}=BPP_{Slow,Stack}=BPP_{Fiber}: A BPP of 0.36 mm*mrad can be chosen because a typical semiconductor diode laser operating at 940 nm in the TEM₀₀ mode has a BPP_{Fast} of 0.3 mm*mrad, which ensures that the beam from 14 such stacked diodes laser will have a BPP_{Fast} that has a 20% safety margin compared to the BPP_{Fast} required.

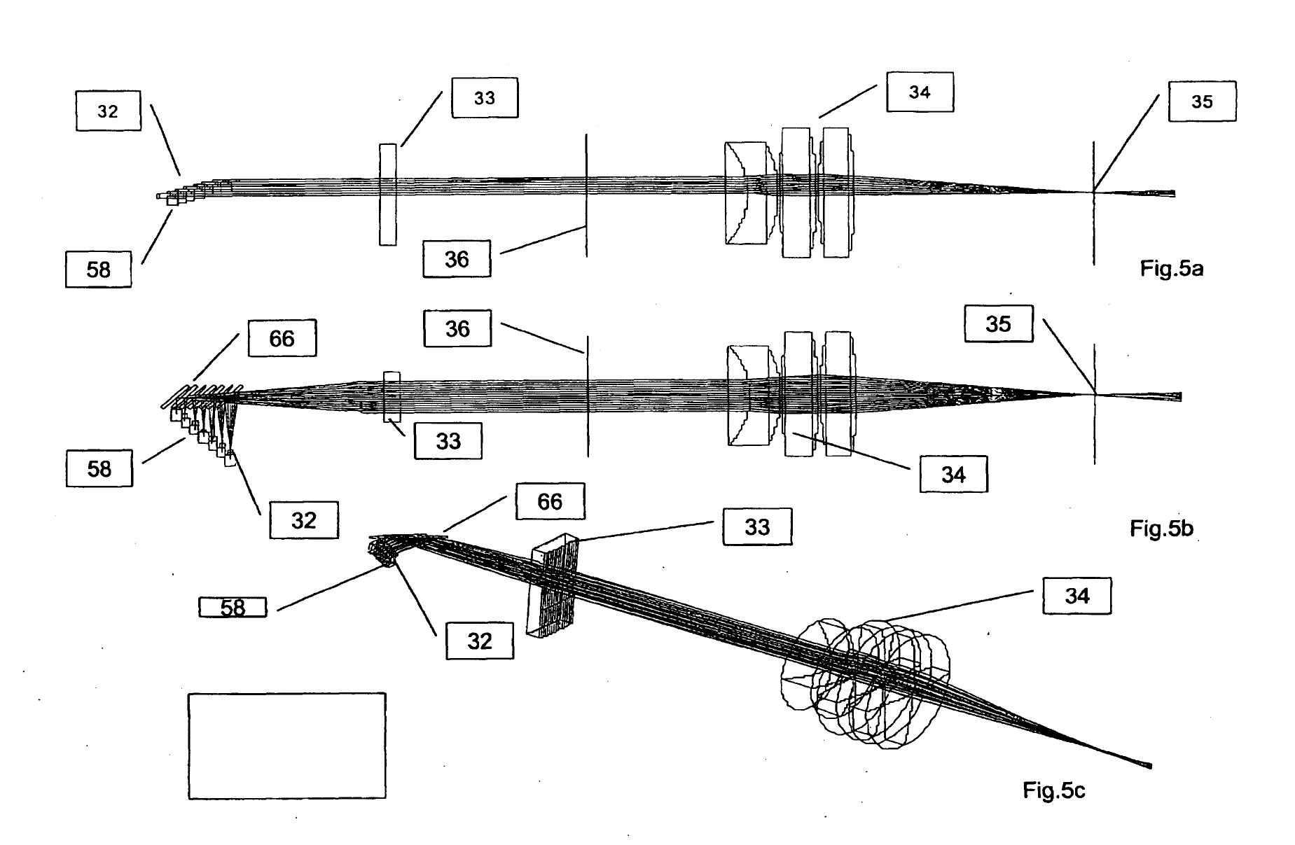

An arrangement of 14 laser diodes 32 for coupling light into fiber having a 100 μm core diameter and requiring a NA of 0.1 is shown in FIGS. 5a, 5b, and 5c. For clarity, only the upper seven emitter of the symmetric arrangement of the 14 emitter stack are shown. The emitters 32 are arranged on a step-shaped holder 58, a cylindrical lens 33 collimates the beams along the slow axis, and an optical system that includes spherical lenses 34 focuses the beams along the fast and slow axes onto the entrance plane 35 of the fiber. The positioning of the laser diodes 32 and the step mirror 66 ensures identical optical path length for all laser beams after deflection.

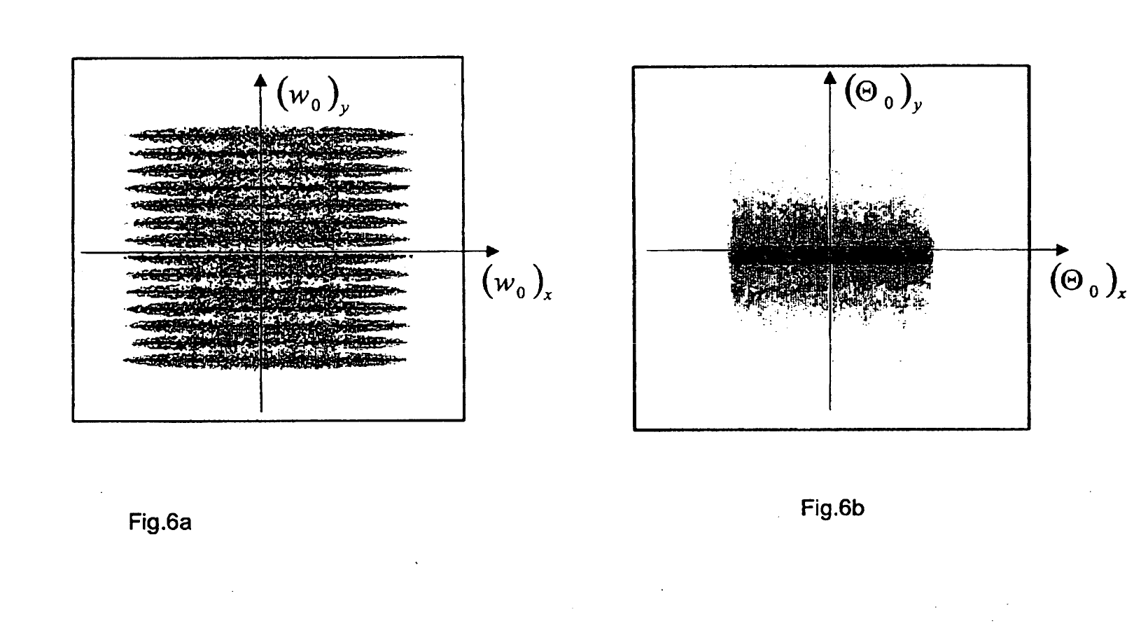

FIG. 6a shows the spatial intensity distribution at the plane 36, which is the back focal plane of lens group 34 shown in FIG. 5. The emission of 14 laser diode emitters are stacked on top of each other in the (w₀)_{y}-direction achieving a fill factor of nearly 100%. The height of this whole stack in (w₀)_{y}-axis is approximately the width of each individual emitter in (w₀)ₓ-axis.

FIG. 6b shows the angular distribution of the same beams at plane 36, which is the focal plane of lens group 34. Along the (Θ₀)_{y}-axis the distribution is Gaussian, and along the (Θ₀)ₓ-axis the distribution is top-hat shaped. The maximum divergence angles in (Θ₀)ₓ- and (Θ₀)_{y}-axis are approximately equal.

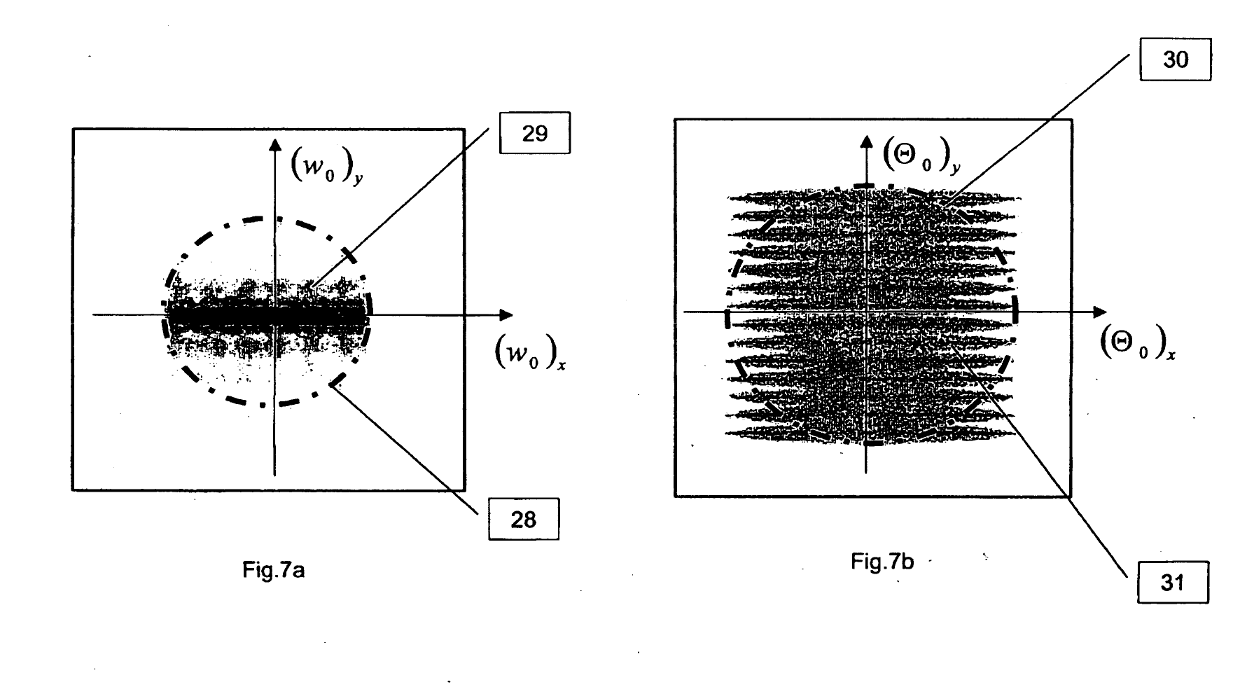

FIGS. 7a and 7b depict the case known as overfilling the fiber. FIG. 7a shows the spatial intensity distribution 29 at the entrance plane 35 of the fiber as shown in FIG. 5 and the fiber diameter 28 in the (w₀)ₓ*(w₀)_{y} space. Radiation of the individual emitters can be focused onto the entrance plane 35 of the fiber and therefore superimposed in plane 35 to form a single Gaussian distribution in the fast axis, (w₀)_{y}. After further propagation of the beam beyond plane 35, the radiation of the different emitters separates again.

FIG. 7b shows the angular intensity distribution 31 at the entrance plane 35 of the fiber of light output from a stack 7 of multiple emitters 6. In angular space, the light output of different emitters separate because of the particular choice of focusing the emitters onto the fiber. The chosen acceptance angle of the fiber (i.e., corresponding to NA=0.1) forms a circle 30 in the (Θ₀)ₓ(Θ₀)_{y} plane, and intensity that lies outside of the acceptance angle 30 is not within the chosen numerical aperture in the fiber. Although a fiber having a numerical aperture greater than 0.1 (e.g., NA=0.22) can guide light outside the circle 30, this light may have an angular divergence that is unacceptable for using in an optical system downstream of the fiber. For example, if the fiber transports light to a materials processing system, the optics of the system might not accept radiation having such large divergence angles. Therefore, the portion of the intensity outside the circle 30 must be considered as lost for downstream applications.

The particular choice of focusing the light onto the fiber is based on the fact that the intensity that lies outside the fiber diameter 28 (FIG. 7a) geometrically accounts for 22% of the area defined by circle 28, however, because this intensity occurs at the tail of the Gaussian intensity distribution of the beam, this intensity amounts to only a small portion of the total beam intensity and can be sacrificed.

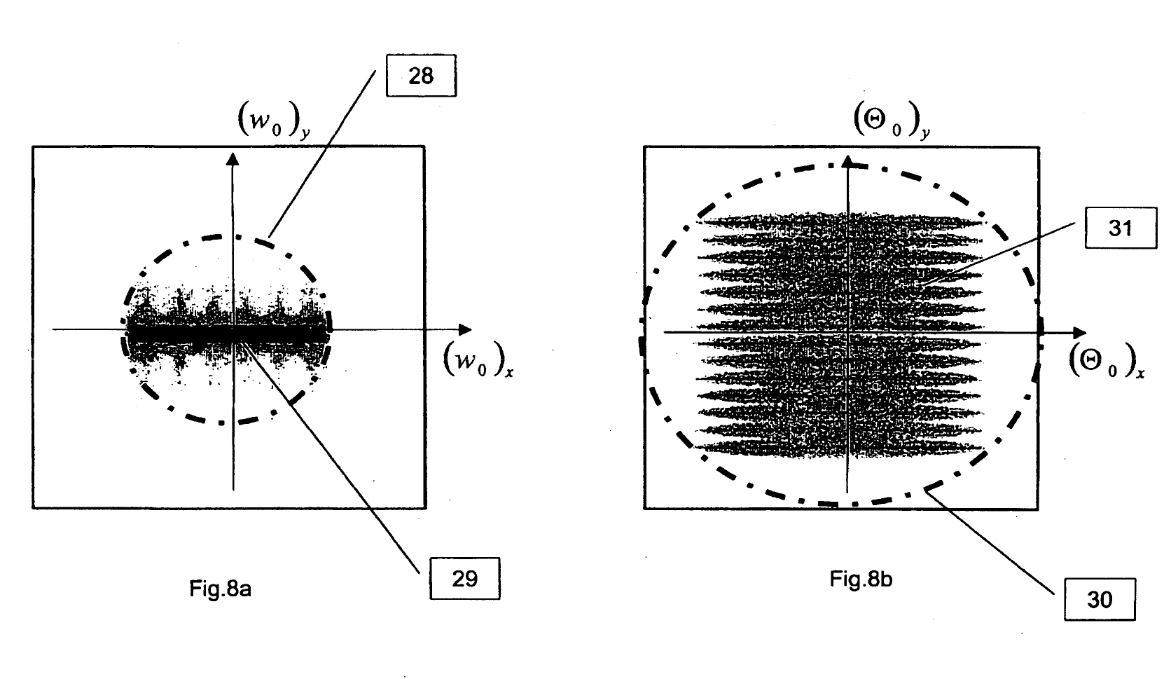

FIGS. 8a and 8b depict the case which we call underfilling the fiber.

FIG. 8a shows the spatial intensity distribution 29 at the entrance plane 35 of the fiber as shown in FIG. 5 and the fiber diameter 28 in the (w₀)ₓ*(w₀)_{y} space. Radiation of the individual emitters can be focused onto the fiber and therefore superimposed in plane 35 forming a single Gaussian distribution in the fast-axis (w₀)_{y}. After further propagation of the beam beyond plane 35, the radiation of the different emitters separates again. This behavior is also reflected in FIG. 8b.

FIG. 8b shows the angular intensity distribution 31 at the entrance plane 35 of the fiber. In angular space the emitters separate because of the particular choice of focusing the emitters onto the fiber. In this case, a higher angle of acceptance for the fiber is chosen (i.e., NA=0.14), which now forms a larger circle 30 in (Θ₀)ₓ(Θ₀)_{y}. It has to be pointed out that this aperture is still smaller than the numerical aperture of the fiber (NA=0.22). However, it has to be ensured that all subsequent optics (i.e., used for materials processing) accept radiation up to angles equivalent to NA=0.14. In currently installed applications, this is not the case, as NA=0.1 is the industry standard for materials processing.

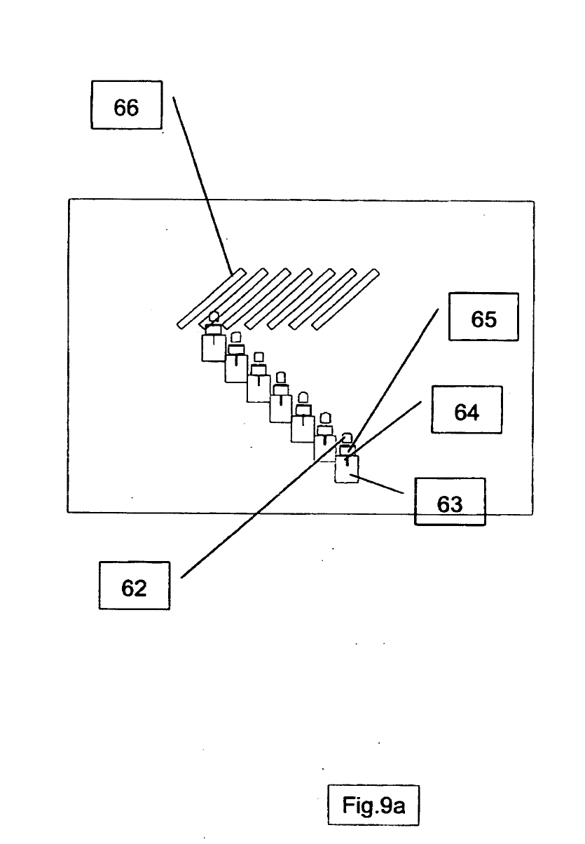

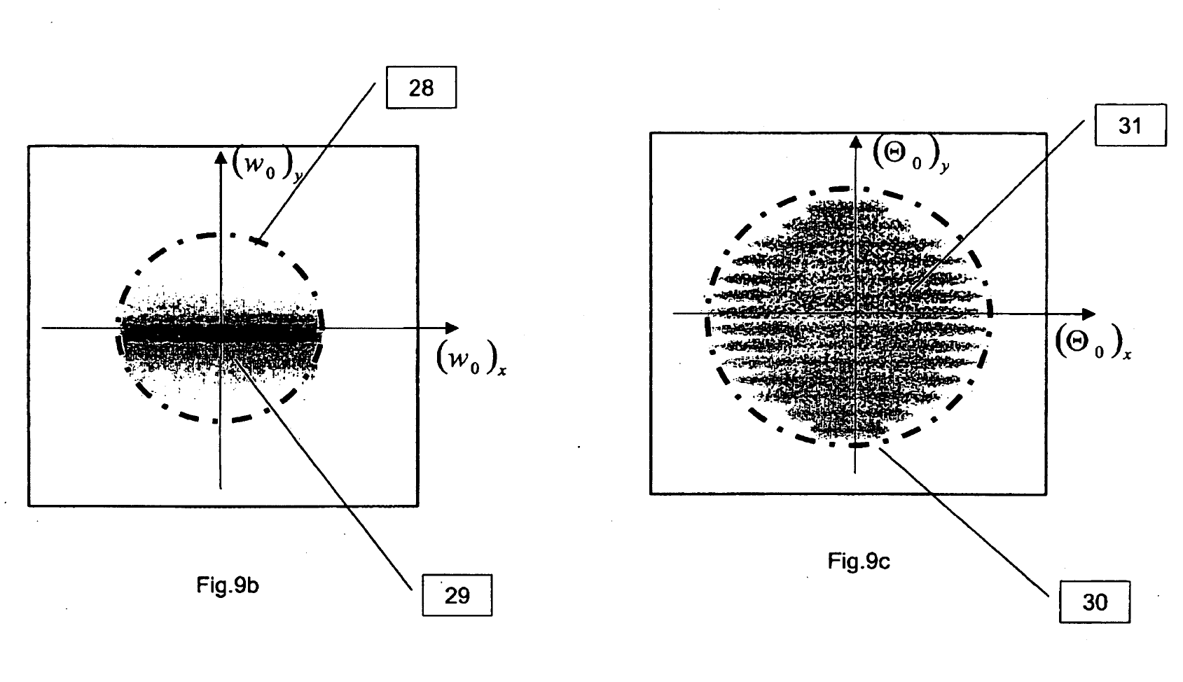

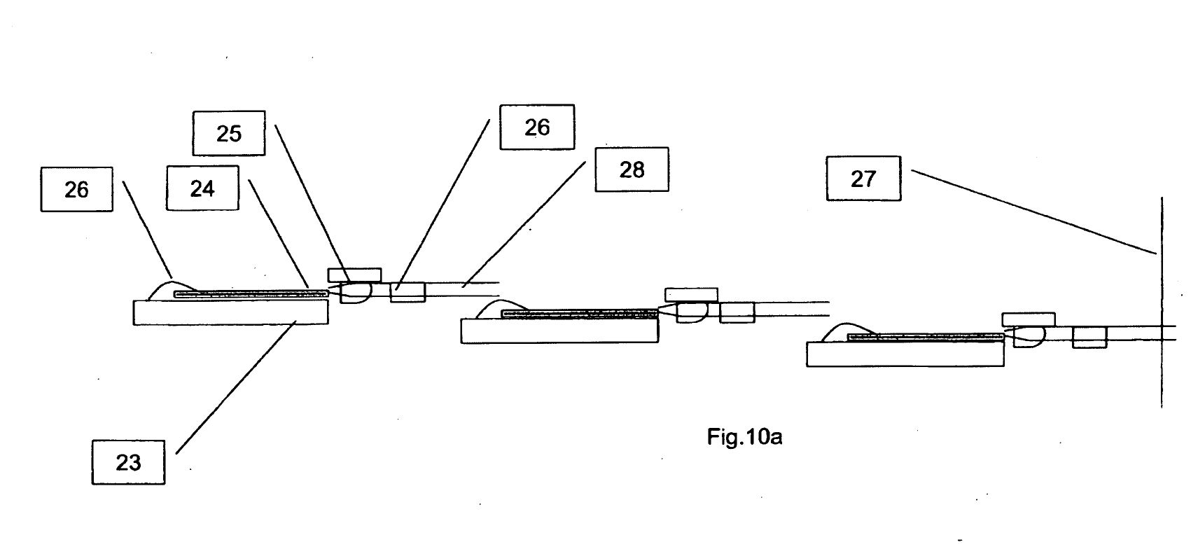

FIGS. 9a, 9b, and 9c depict the case which we call optimum filling the fiber, In this case (FIG. 9a) single emitters 65 having different widths as tabulated in Table 1 are placed on submounts 63 and collimated using a fast-axis collimation 64 and a slow-axis collimation 62 before being deflected by the steps of a step mirror 66. Again, the positioning of the laser diodes 65 and the step mirror 66 ensures identical optical path length for all laser beams after deflection. For clarity, only the upper seven emitter of the symmetric arrangement of the 14 emitter stack are shown. Table 1 shows that because of the different individual chosen widths of the emitters (wₛₜᵣᵢₚₑ), the beam parameter product varies for the individual emitters, when the divergence angle of the single emitters remains constant. Alternatively, the divergence angle of the individual emitters could be varied to achieve a variation in the BPP of the different emitters, and such a system would not require slow-axis collimation lenses 62.

TABLE 1

| | (BPP)ᵢ | theta | Wₛₜᵣᵢₚₑ |
|---|---|---|---|
| Element | (mm * mrad) | (rad) | (μm) |
| 1 | 1.86 | 0.1 | 37.12 |
| 2 | 3.09 | 0.1 | 61.86 |
| 3 | 3.83 | 0.1 | 76.60 |
| 4 | 4.33 | 0.1 | 86.60 |
| 5 | 4.67 | 0.1 | 93.40 |
| 6 | 4.88 | 0.1 | 97.68 |
| 7 | 4.99 | 0.1 | 99.74 |
| 8 | 4.99 | 0.1 | 99.74 |
| 9 | 4.88 | 0.1 | 97.68 |
| 10 | 4.67 | 0.1 | 93.40 |
| 11 | 4.33 | 0.1 | 86.60 |
| 12 | 3.83 | 0.1 | 76.60 |
| 13 | 3.09 | 0.1 | 61.86 |
| 14 | 1.86 | 0.1 | 37.12 |

FIG. 9b shows the spatial intensity distribution 29 at the entrance plane 35 of the fiber as shown in FIG. 5 and the fiber diameter 28 in the (w₀)x*(w₀)y space. The radiation of the individual emitters is focused onto the fiber and therefore superimposed in plane 35 forming a single Gaussian distribution in the fast-axis (w₀y). After further propagation of the beam beyond plane 35, the radiation of the different emitters separates again. FIG. 9c shows the angular intensity distribution 31 at the entrance plane 35 of the fiber. In angular space, the emitters separate because of the particular choice of focusing the emitters onto the fiber. In this case, due to the varying BPP of the individual emitters the entire intensity is contained inside the chosen fiber acceptance angle (in this case NA=0.1), which forms a circle in the (Θ₀)ₓ(Θ₀)_{y} space. In this manner the entire power of all emitters 32 (FIG. 5) is contained within the given numerical aperture and can be delivered through all subsequent optics, i.e., for materials processing. Such a system is optimum in the respect that it shows maximum efficiency and brightness for a given choice of fiber core diameter and fiber acceptance angle (in this case corresponding to NA=0.1).

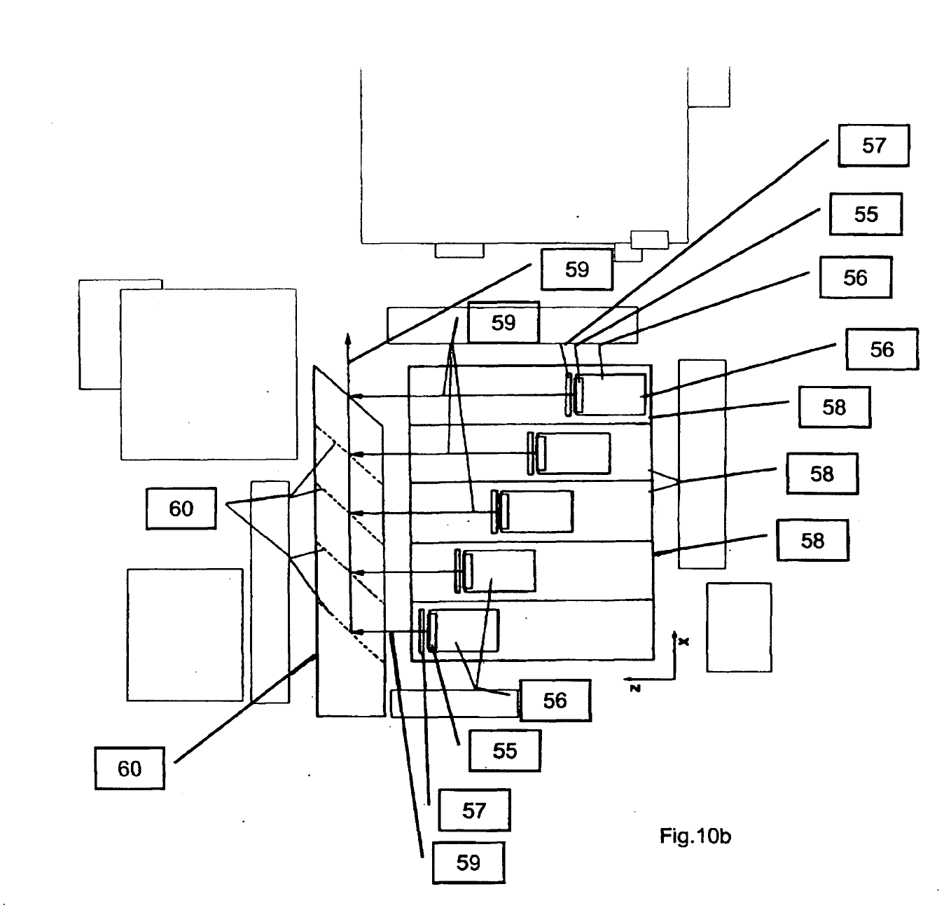

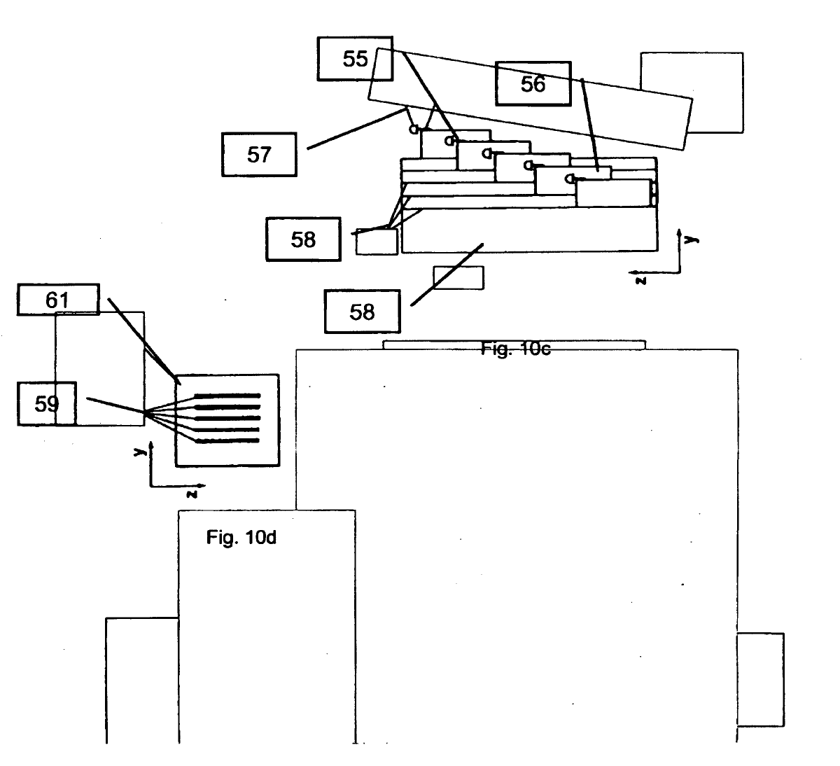

To achieve the spatial and angular light intensity distributions described above at the entrance to the fiber it is not necessary to generate the light from multiple laser diode arrays that are mechanically stacked on top of each other. Such a distribution can also be achieved by combining the light output from multiple arrays 23 that are not in contact with each other, as shown in FIG. 10a. Different arrays 23 can be positioned behind each other at different heights in the vertical axis. The difference in height between neighboring arrays 23 can be equal or close to the height of the collimated beams 28 emitted by individual arrays, to ensure a high fill factor of the combined beam. The light emerging from the emitting zone 24 of an individual array is collimated in the fast axis with a lens 25. The lens 25 can be shaped so that the upper edge of the lens 25 does not extend above the collimated beam 28, so that it does not interfere with a beam emitted from another array, and the focal length of the lens 25 can be chosen, so that the half-height of the collimated beam is larger than the mechanical or electrical contacts 26 to the laser diode arrays to ensure a high fill factor in the combined beam due to the light emitted from all the arrays 23. Because the optical path length from an array 23 to a reference surface 27 (e.g., an of a fiber into which the light is coupled) is different for each array 23, slow axis collimation elements 26 can be used to effectively reduce the effect of this difference on the BPP_{slow} of the combined beam. An advantage of such a configuration is that the beams emitted from arrays 23 need not be redirected to reach the optical fiber.

FIGS. 10b and 10c show an optical system that can be used to stack the light output 59 of several arrays 55, as describe in U.S. Pat. No. 6,124,973, which is incorporated herein by reference. The different arrays 55 are mounted on submounts 56 that are positioned on a step-shaped holder 58, where the relative height of the steps can be adapted to achieve a high fill factor of the combined beam due to the output 59 of all the arrays 55. The beams 59 from the different arrays 55 are collimated by fast axis collimating lenses 57 and redirected (e g., reflected) by the surface of an optical element that can also have step structures 60 for reflecting beams from the individual arrays 55, so that the beams 59 emitted from the individual arrays 55 are combined in a pattern, such that stripes of light due to different arrays 55 are arranged in a vertical direction, perpendicular to the lengths of the stripes. The combined light output pattern 61 of the beams 59 from the individual arrays 55 is shown in FIG. 10d.

To reduce the number of mechanical elements, certain elements in a stack 7 of arrays 6 can be grouped together in a mounting module, which is described and shown in co-pending U.S. Patent Application filed concurrently herewith by us and entitled DIODE LASER ARRAY MOUNT.

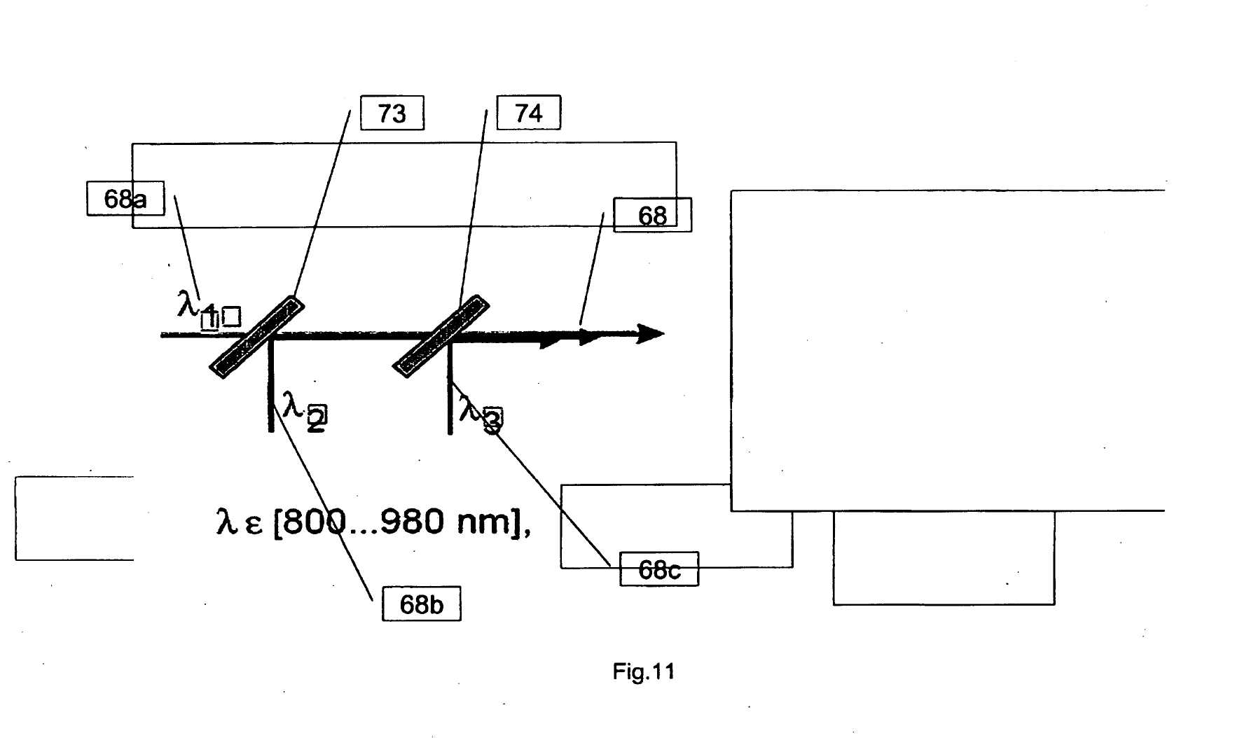

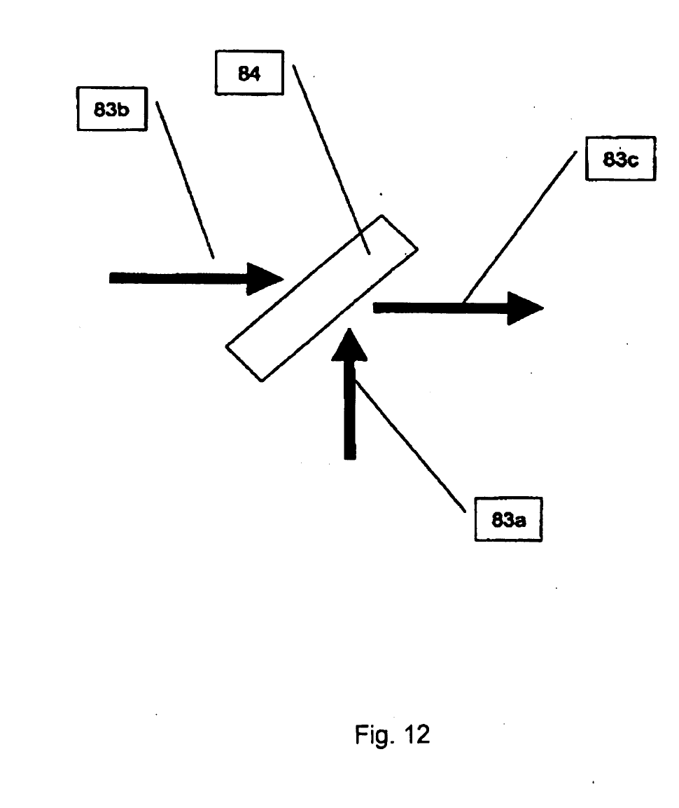

As shown in FIG. 11, several narrow bandwidth reflectors 73 and 74 can be used to combine multiple laser beams 68a, 68b, and 68c having different wavelengths, λ₁, λ₂, and λ₃, respectively, into a single spatially-overlapping beam 68. The reflectivity spectrum of the narrow bandwidth reflector 73 can be selected to reflect beam 68b having wavelength λ₂, but to be transparent to beam 68a having wavelength λ₁. Similarly, the reflectivity spectrum of the narrow bandwidth reflector 74 is selected to reflect beam 68c having wavelength λ₃, but to be transparent to beams 68a and 68b having wavelengths λ₁ and λ₂, respectively. Because the reflectivity spectra of the reflectors 73 and 74 are relatively narrow, the individual beams 68a, 68b, and 68c can be combined in space without sacrificing power or beam quality of the combined output beam 68.

FIG. 12 shows an example of polarization coupling of two beams 83a and 83b where the polarization plane of the two beams are perpendicular. Optical element 84 that transmits a beam 83b and reflects a beam 83a. This element could be a glass plate with dielectric coatings or a birefringent crystal.

Other details regarding particular embodiments may be found in pending U.S. Provisional Patent Application Ser. No. 60/575,390, filed on Jun. 1, 2004, or in a U.S. Patent Application filed concurrently herewith by us and entitled DIODE LASER ARRAY MOUNT. The entire contents of both of these mentioned applications are hereby incorporated by reference.

A number of embodiments of the invention have been described. Nevertheless, it will be understood that various modifications may be made without departing from the spirit and scope of the invention. Accordingly, other embodiments are within the scope of the following claims.

1. A light generating apparatus operably coupled to an optical fiber with a cladding and a core defining a core diameter, wherein the optical fiber has a numerical aperture and the product of the numerical aperture of the fiber and one-half the diameter of the core is less than or substantially equal to 400 millimeter-milliradians, the apparatus comprising:
a plurality of laser diode arrays, each array comprising at least one light emitting region adapted for emitting light in a individual beam wherein the plurality of laser diode arrays are arranged such tat light from the individual beams is combined in a combined beam, the combined beam having a first far-field, half-angle divergence in a first direction and a first waist dimension in the first direction, and a second far-field, half-angle divergence in a second direction, substantially perpendicular to the first direction, and a second waist dimension in the second direction,
wherein the laser diode arrays are arranged relative to the optical fiber to couple light output from the laser diode arrays into the core of the fiber at an end of the fiber,
wherein the product of the first far-field, half-angle divergence and the first waist dimension is equal to or smaller than one-half of the product of the core diameter and a numerical aperture of the fiber, and
wherein the product of the second far-field, half-angle divergence and the second waist dimension is equal to or smaller than one-half of the product of the core diameter and the numerical aperture.

2. The light generating apparatus of claim 1, wherein the product of the numerical aperture of the fiber and one-half the diameter of core is less than or substantially equal to 110 millimeter-milliradians, particularly less than or substantially equal to 6 millimeter-milliradians.

3. The light generating apparatus of claim 1, wherein the at least one light emitting region is a multi-mode light emitting region.

4. The light generating apparatus of claim 1, wherein each laser diode array comprises a plurality of M light emitting regions, where M is an integer.

5. The light generating apparatus of claim 4, wherein each light emitting region of each laser diode array comprises a swipe width (wₛ) and wherein the light emitting regions of a laser diode array are arranged adjacent to each other and are separated from adjacent regions by a center-to-center distance (pₛ).

6. The light generating apparatus of claim 1, wherein the arrays define both a fast axis and a slow axis, the apparatus further comprising a lens for collimating light emitted in an individual beam from each laser diode array along a direction of the slow axis.

7. The light generating apparatus of claim 6, wherein each laser diode array comprises a plurality of M light emitting regions arranged adjacent to each other and separated from adjacent regions by a center-to-center distance (pₛ), where M is an integer, wherein the individual beam has a waist dimension (w_{beam}) after collimation by the lens in a direction substantially parallel to the slow axis, and wherein the first waist dimension is substantially equal to 0.5·[(M−1)·p+2·w_{beam}].

8. The light generating apparatus of claim 1, wherein the plurality of laser diode arrays is arranged such that light output from individual laser diode arrays is coupled into the fiber core in substantially parallel stripes of light.

9. The light generating apparatus of claim 1, wherein the plurality of laser diode arrays are arranged in a stack and include N laser diode arrays, where N is an integer.

10. The light generating apparatus of claim 9, wherein each laser diode array has a light emitting region that has a height (t), and wherein the laser diode arrays are stacked to have a center-to-center distance (qₛ) between adjacent laser diode arrays in the stack, such that the second waist dimension is substantially equal to 0.5·[(N−1)·qₐ+t].

11. The light generating apparatus of any of claim 1, wherein the laser diode arrays define a fast axis and a slow axis, the apparatus further comprising a microlens corresponding to each laser diode array for collimating light emitted in individual beams from each laser diode array along the direction of the fast axis.

12. The apparatus of claim 11, wherein the apparatus comprises a plurality of N arrays, where N is an integer, wherein individual beams have a waist dimension after collimation by the microlenses in a direction substantially parallel to the fast axis (h), wherein the individual beams are combined in a stack of beams, such that adjacent beams in the stack have a center-to-center distance, qₛ, and wherein the second waist dimension is substantially equal to 0.5·[(N−1)·qₛ+h].

13. The light generating apparatus of claim 1, herein the light emitting regions comprise multimode emitting regions.

14. The light generating apparatus of claim 1,
wherein the product of the first far-field, half-angle divergence and the first waist dimension is equal to or smaller than 1/2\sqrt{2} times the product of one-half the core diameter and the numerical aperture, and
wherein the product of the second far-field, half-angle divergence and the second waist dimension is equal to or smaller than 1/2\sqrt{2} times the product of one-half the core diameter and the numerical aperture.

15. The light generating apparatus of claim 1, wherein the plurality of laser diode arrays comprises N laser diode arrays, where N is an integer,
wherein the beams of the N laser diode arrays are combined in a combined beam composed of a stack of substantially parallel light stripes of individual beams from the individual laser diode arrays,
wherein an individual beam emitted from an individual laser diode array has a first far-field, half-angle divergence (Θ₁ⁱ) and a first waist dimension (w₁ⁱ) in a direction substantially parallel to a the first direction, and a second far-field, half-angle divergence (Θ₂), and a second waist dimension (w₂) in a direction substantially parallel to the second direction,
wherein the product of Θ₁ⁱ and w₁ⁱ, for an i^{th} parallel light stripe in the combined beam is equal to or smaller than the product of the one-half one-half the core diameter, (d), the numerical aperture (NA), and the factor
$$\sqrt{1 - {( \frac{- NA \cdot \frac{d}{2} + 2 \cdot ( i - \frac{1}{2} ) \cdot {Θ}_{2} \cdot {w}_{2}}{NA \cdot d / 2} )}^{2}} ,$$
where i is an integer index that takes the value i=1 . . . N, representing sequentially the i^{th} parallel light stripe in the combined beam, where the first light stripe is at the bottom of the stack and the N^{th} light stripe is at the top of the stack, and
wherein the product of Θ₂ and w₂ is equal to or smaller than product of one-half the core diameter and the numerical aperture.

16. The light generating apparatus of claim 15, wherein the at least one light emitting region is a multi-mode light emitting region.

17. The light generating apparatus of, wherein each laser diode array comprises a plurality of M light emitting regions, where M is an integer.

18. The light generating apparatus of claim 15, wherein each light emitting region comprises a stripe width (wₛ), and wherein the light emitting regions of a laser diode array are arranged adjacent to each other and are separated from adjacent regions by a center-to-center distance (pₛ).

19. The light generating apparatus of claim 15, wherein the laser diode arrays include a fast axis and a slow axis, the apparatus further comprising a lens for collimating light emitted in an individual beam from each laser diode array along the direction of the slow axis.

20. The light generating apparatus of claim 15, wherein the plurality of N laser diode arrays are arranged in a stack, each light emitting region having a height (t), wherein the laser diode arrays are stacked such that adjacent laser diode arrays in the stack have a center-to-center distance (qₛ), and wherein the second waist dimension is substantially equal to 0.5·[(N−1)·qₛ+t].

21. The light generating apparatus of claim 15, wherein the laser diode arrays define a fast axis and a slow axis, the apparatus further comprising a microlens corresponding to each laser diode array for collimating light emitted in individual beams from each laser diode array along a direction of the fast axis.

22. The light generating apparatus of claim 21, wherein individual beams have a waist dimension after collimation by the microlenses in a direction substantially parallel to the fast axis (h), wherein the individual beams are combined in a stack, such that adjacent beams in the stack have a center-to-center distance (qₛ), and wherein the second waist dimension is substantially equal to 0.5·[(N−1)·qₛ+h].

23. The light generating apparatus of claim 5, wherein the first waist dimension is substantially equal to 0.5·[(M−1)·pₛ+wₛ].

24. The light generating apparatus of claim 13, wherein the multimode emitting regions are at least 10 μm wide.
